(19) United States
(12) Patent Application Publication
(10) Pub. No.: US 2014/0325299 A1
(43) Pub. Date: Oct. 30, 2014

(54) TESTING SYSTEM AND TESTING METHOD FOR MOTHERBOARD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: BI-HUI TAN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/147,633

(22) Filed: Jan. 6, 2014

(30) Foreign Application Priority Data
Apr. 30, 2013 (CN) 2013101555135

(51) Int. Cl. G01R 31/3177

(52) U.S. Cl. CPC G01R 31/3177
USPC 714/727

(57) ABSTRACT

A testing system includes a computer, a testing circuit board, and a motherboard. The testing circuit board includes a programmable logic device connected to the computer. The programmable logic device includes a predetermined signal. The programmable logic device is used to output an excitation signal to the motherboard. The motherboard is used to generate a back signal according to the excitation signal. The programmable logic device is used to analyze whether the back signal is consistent with the predetermined signal. The computer is used to display a testing result output by the programmable logic device. The disclosure further offers a testing method.

### BACKGROUND

1. Technical Field

The present disclosure relates to testing systems and testing methods, and more particularly to a testing system and a testing: method for a motherboard.

2. Description of Related Art

Before assembling a motherboard into an electronic device, the motherboard requires testing to test functions of the motherboard. However, excitation signals for testing the motherboard are generated manually to detect whether functions of the motherboard are qualified. Thus, the testing process is inconvenient and slow. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like-reference numerals designate corresponding parts throughout the several views.

FIG. 1 is a block diagram of an embodiment of a testing system.

FIGS. 2A-2B are a flowchart of an embodiment of a testing method.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

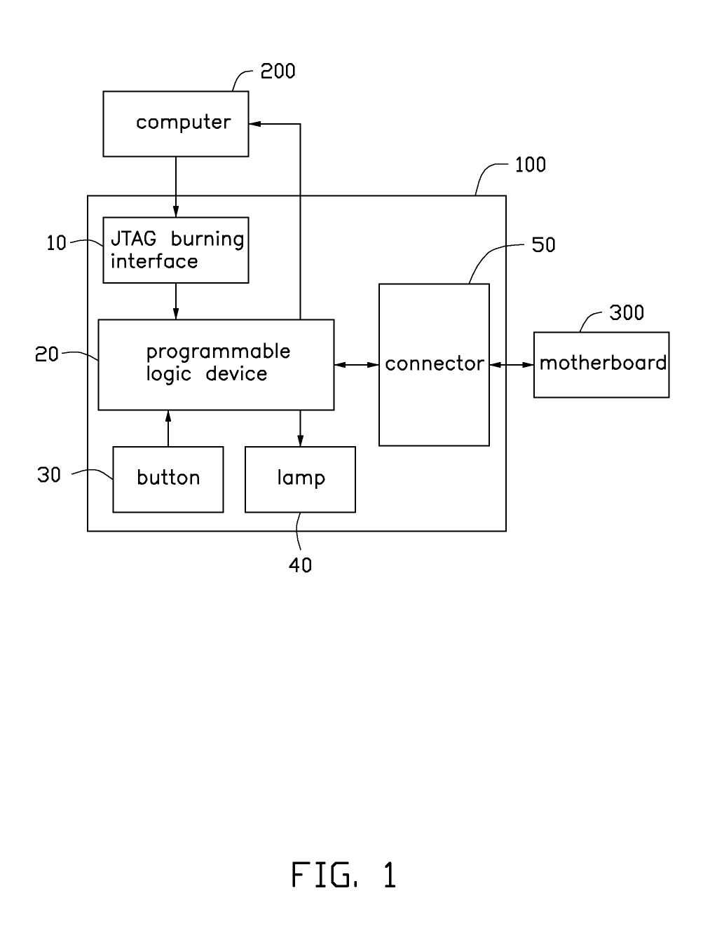

FIG. 1 illustrates an embodiment of a testing system. The testing system comprises a testing circuit board 100, a computer 200 electrically connected to the testing circuit board 100, and a motherboard 300 to be tested. The computer 200 can be a notebook, a tablet computer, or the like having a display screen.

The testing circuit board 100 comprises a Joint Test Action Group (JTAG) burning interface 10, a programmable logic device 20, a plurality of buttons 30 (only one is shown in FIG. 1), a lamp 40, and a connector 50. The programmable logic device 20 is electrically connected to the JTAG burning interface 10. In one embodiment, the programmable logic device 20 is a Complex Programmable Logic Device (CPLD) or to Field Programmable Gate Array (FPGA). The JTAG burning interface 10 is electrically connected to the computer 200. The computer 200 comprises a plurality of procedural instructions. Thus, the programmable logic device 20 can obtain the plurality of procedural instructions via the JTAG burning interface 10. The plurality of buttons 30 is electrically connected to the programmable logic device 20. The plurality of buttons 30 is used to select one corresponding excitation signal in the programmable logic device 20. When one of the plurality of buttons 30 is pressed, one corresponding excitation signal in the programmable logic device 20 is selected. The lamp 40 is electrically connected to the programmable logic device 20 and is lit up to show that the programmable logic device 20 is operating. The connector 50 is electrically connected to the programmable logic device 20 and the motherboard 300. The motherboard 300 is used to generate a hack signal according to the excitation signal. The connector 50 is used to transmit the excitation signals of the programmable logic device 20 to the motherboard 300, and transmit the back signal of the motherboard 300 to the programmable logic device 20.

In use, a predetermined signal and a predetermined excitation signal are stored in the programmable logic device 20. The programmable logic device 20 generates an excitation signal, and the excitation signal is transmitted to the motherboard 300 via the connector 50. The motherboard 300 receives the excitation signal and generates a back signal according to the excitation signal. The back signal of the motherboard 300 is transmitted to the programmable logic device 20 via the connector 50. When the programmable logic device 20 receives the back signal, the programmable logic device 20 compares the back signal with the predetermined signal to obtain a testing result. The testing result can be transmitted to the computer 200 to be displayed. For example, when the back signal is less than or greater than the predetermined signal, the motherboard 300 fails the test, and the testing result, such as “testing failed” is displayed on the display screen of the computer 200.

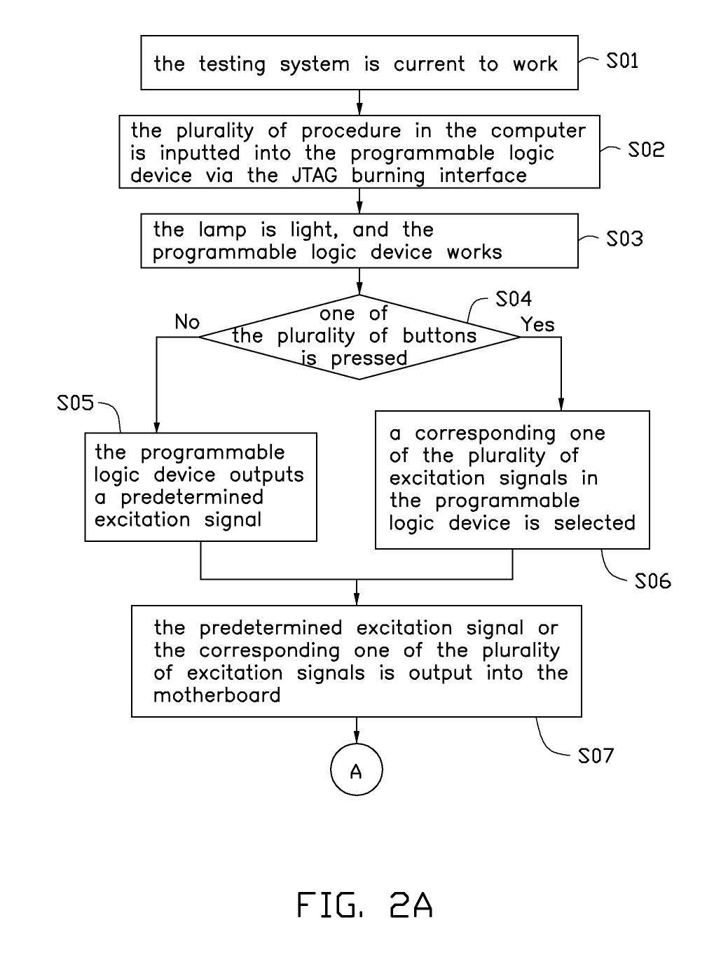

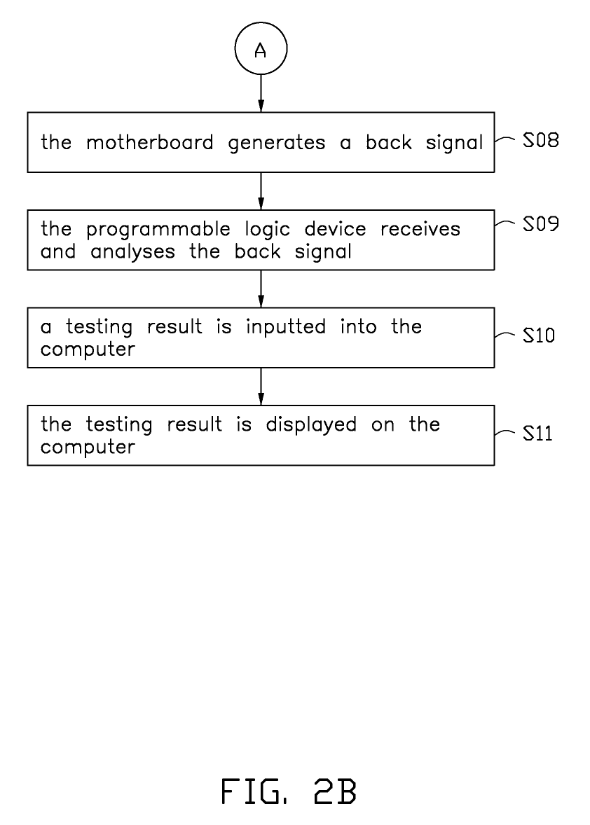

FIGS. 2A-2B cooperatively illustrate an embodiment of a testing method. The method comprises the following steps:

S01: the computer 200, the testing circuit board 100, and the motherboard 300 are provided.

S02: the plurality of procedural instructions in the computer 200 is inputted into the programmable logic device 20 via the JTAG burning interface.

S03: the lamp 40 is light to indicate the programmable logic device 20 is working.

S04; the programmable logic device 20 detects whether one of the plurality of buttons 30 is pressed. If no button 30 is pressed, the method goes on to step S05. If one of the plurality of buttons 30 is pressed, the method goes on to step S06.

S05: the programmable logic device 20 outputs a predetermined excitation signal.

S06: one excitation signal corresponding to the button 30 pressed is selected.

S07: the predetermined excitation signal or the corresponding excitation signal is output to the motherboard 300 via the connector 50.

S08: the motherboard 300 receives the predetermined excitation signal or the corresponding excitation signal, and generates and sends a corresponding back signal to the programmable logic device 20 via the connector 50.

S09: The programmable logic device 20 receives and analyses the back signal. When the back signal is consistent with the predetermined signal, the motherboard 300 is qualified, and a testing result, such as “testing success,” is generated. When the back signal is less than or greater than the predetermined signal, the motherboard 300 is unqualified, and a testing result, such as “testing failed,” is generated.

S10: the testing result is inputted into the computer 200 by the programmable logic device 20.

S11: the testing result, such as “testing success” or “testing failed,” is displayed on the display screen of the computer 200.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A testing system comprising:
a computer; and
a testing circuit board configured to connect to a motherboard; the testing circuit board comprising a programmable logic device connected to the computer; the programmable logic device comprising a predetermined signal;
wherein the programmable logic device is configured to output an excitation signal to the motherboard; the motherboard is configured to generate a back signal according to the excitation signal; the programmable logic device is configured to analyze whether the back signal is consistent with the predetermined signal; and the computer is configured to display a testing result analyzed by the programmable logic device.

2. The testing system of claim 1, wherein the testing circuit board further comprises a Joint Test Action Group (JTAG) burning interface connected to the programmable logic device and the computer, the computer comprises a plurality of procedural instructions, and the JTAG burning interface is configured to transmit the plurality of procedural instructions to the programmable logic device.

3. The testing system of claim 1, wherein the testing circuit board further comprises a button connected to the programmable logic device, and the button is configured to select to a type of the excitation signal.

4. The testing system of claim 1, wherein the testing circuit board further comprises a lamp connected to the programmable logic device, and the lamp is configured to display a working position of the programmable logic device.

5. The testing system of claim 1, wherein the testing circuit board further comprises a connector connected to the programmable logic device and the motherboard, and the connector is configured to transmit the excitation signal to the motherboard.

6. The testing system of claim 1, wherein the programmable logic device is a Complex Programmable Logic Device (CPLD).

7. The testing system of claim 1, wherein the programmable logic device is a Field Programmable Gate Array (FPGA).

8. A testing method comprising:
supplying a programmable logic device to generate an excitation signal; and a predetermined signal stored in the programmable logic device;
inputting the excitation signal to a motherboard by the programmable logic device;
generating a back signal according to the excitation signal by the motherboard;
analyzing whether the back signal is consistent with the predetermined signal by the programmable logic device;
obtaining a testing result by the programmable logic device; and
displaying the testing result by a computer.

9. The testing method of claim 8, further comprising: burning a plurality of procedural instructions of the computer into the programmable logic device via a Joint Test Action Group (JTAG) burning interface, before inputting the excitation signal to the motherboard by the programmable logic device.

10. The testing method of claim 8, further comprising: detecting whether a button connected to the programmable logic device is pressed, when the button is not pressed, a predetermined excitation signal is inputted into the motherboard by the programmable logic device; and when the button is pressed, a corresponding excitation signal according to the button that was selected, is inputted into the motherboard by the programmable logic device, before inputting the excitation signal to the motherboard by the programmable logic device.

11. The testing method of claim 8, further comprising: lighting a lamp when the programmable logic device is working.

12. The testing method of claim 8, further comprising: connecting the programmable logic device to the motherboard by a connector, and transmitting the excitation signal to the motherboard via the connector.

13. The testing method of claim 8, wherein the programmable logic device is a Complex Programmable Logic Device (CPLD).

14. The testing method of claim 8, wherein the programmable logic device is a Field Programmable Gate Array (FPGA).
